(19) United States
(12) Patent Application Publication
(10) Pub. No.: US 2020/0041898 A1
(43) Pub. Date: Feb. 6, 2020

(54) RADIATION-SENSITIVE COMPOSITION AND RESIST PATTERN-FORMING METHOD

(71) Applicant: JSR CORPORATION, Tokyo (JP)

(72) Inventors: Hisashi NAKAGAWA, Tokyo (JP); Yusuke ASANO, Tokyo (JP); Takehiko NARUOKA, Tokyo (JP)

(73) Assignee: JSR CORPORATION, Tokyo (JP)

(21) Appl. No.: 16/595,884

(22) Filed: Oct. 8, 2019

Related U.S. Application Data
(63) Continuation of application No. PCT/JP2018/011022, filed on Mar. 20, 2018.

(30) Foreign Application Priority Data
Apr. 11, 2017 (JP) 2017-078210

(51) Int. Cl. G03F 7/004; G03F 7/20

(52) U.S. Cl. CPC G03F 7/0045; G03F 7/2059; G03F 7/2004

(57) ABSTRACT

A radiation-sensitive composition includes particles and a solvent. The particles include a first component and a second component. The first component is a hydrolyzation product or a hydrolytic condensation product of a metal compound including a hydrolyzable group, or a combination thereof; and the second component is an organic acid, an anion of the organic acid, a first compound represented by formula (1), or a combination thereof. The organic acid and the first compound each have a molecular weight of no less than 120. In the formula (1), R¹ represents an organic group having a valency of n; X represents an alcoholic hydroxyl group, —NCO or —NHR^{a}, wherein R^{a} represents a hydrogen atom or a monovalent organic group; and n is an integer of 2 to 4.

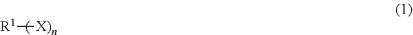

### CROSS-REFERENCE TO RELATED APPLICATIONS

The present application is a continuation application of International Application No. PCT/JP2018/011022, filed Mar. 20, 2018, which claims priority to Japanese Patent Application No. 2017-078210, filed Apr. 11, 2017. The contents of these applications are incorporated herein by reference in their entirety.

### BACKGROUND OF THE INVENTION

### Field of the Invention

The present invention relates to a radiation-sensitive composition and a resist pattern-forming method.

### Discussion of the Background

General radiation-sensitive compositions for use in microfabrication by lithography generate acids at light-exposed regions upon irradiation with electromagnetic waves such as a far ultraviolet ray (e.g., ArF excimer laser beam, KrF excimer laser beam, etc.) or an extreme ultraviolet ray (EUV), a charged particle ray such as an electron beam. A chemical reaction in which the acid serves as a catalyst causes the difference in rates of dissolution in a developer solution, between light-exposed regions and light-unexposed regions to form a resist pattern on a substrate. The resist pattern thus formed can be used as a mask or the like in substrate processing.

Such radiation-sensitive compositions are demanded to have improved resist performances along with miniaturization in processing techniques. To meet such demands, types, molecular structures and the like of polymers, acid generating agents and other components which may be used in the compositions have been investigated, and combinations thereof have been further investigated in detail (see, Japanese Unexamined Patent Application, Publication Nos. H11-125907, H8-146610 and 2000-298347).

Accordingly, miniaturization of patterns has proceeded to a level for line widths of no greater than 40 nm at present. However, radiation-sensitive compositions are required to have a still higher level of resist performance, and in particular, demanded are capabilities of forming resist patterns with superior developability and high dissolution contrast between the light-exposed regions and the light-unexposed regions, as well as high sensitivity even in cases of EUV and electron beams being used.

### SUMMARY OF THE INVENTION

According to an aspect of the present invention, a radiation-sensitive composition includes particles and a solvent. The particles include a first component and a second component. The first component is a hydrolyzation product or a hydrolytic condensation product of a metal compound including a hydrolyzable group, or a combination thereof; and the second component is an organic acid, an anion of the organic acid, a first compound represented by formula (1), or a combination thereof. The organic acid and the first compound each have a molecular weight of no less than 120. In the formula (1), R¹ represents an organic group having a valency of n; X represents an alcoholic hydroxyl group, —NCO or —NHR^{a}, wherein R^{a} represents a hydrogen atom or a monovalent organic group; and n is an integer of 2 to 4.

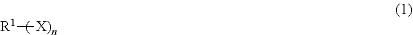

According to another aspect of the present invention, a resist pattern-forming method includes applying the radiation-sensitive composition, directly or indirectly on at least one face side of a substrate to form a resist film, exposing the resist film; and developing the resist film exposed.

### DESCRIPTION OF THE EMBODIMENTS

According to one embodiment of the invention, a radiation-sensitive composition contains particles (hereinafter, may be also referred to as “(A) particles” or “particles (A)”) and a solvent (hereinafter, may be also referred to as “(B) solvent” or “solvent (B)”), wherein the particles (A) include a first component (hereinafter, may be also referred to as “(a) component” or “component (a)”) and a second component (hereinafter, may be also referred to as “(b) component” or “component (b)”), the component (a) is a hydrolyzation product or a hydrolytic condensation product of a metal compound (hereinafter, may be also referred to as “(p) metal compound” or “metal compound (p)”) having a hydrolyzable group, or a combination thereof; and the component (b) is an organic acid (hereinafter, may be also referred to as “(x) organic acid” or “organic acid (x)”), an anion of the organic acid (x), a first compound (hereinafter, may be also referred to as “(y) compound” or “compound (y)”) represented by the following formula (1), or a combination thereof, and wherein the organic acid (x) and the compound (y) each have a molecular weight of no less than 120,

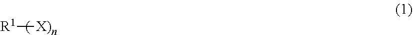

wherein, in the formula (1), R¹ represents an organic group having a valency of n; X represents an alcoholic hydroxyl group, —NCO or —NHR^{a}, wherein R^{a} represents a hydrogen atom or a monovalent organic group; and n is an integer of 2 to 4, wherein a plurality of Xs are identical or different.

According to other embodiment of the invention, a resist pattern-forming method comprises: applying the radiation-sensitive composition of the one aspect directly or indirectly on at least one face side of a substrate; exposing a resist film formed by the applying; and developing the resist film exposed.

The term “organic acid” as referred to herein means an acidic organic compound.

The radiation-sensitive composition of the one embodiment of the present invention is superior in developability and sensitivity. The resist pattern-forming method of the other embodiment of the present invention enables a favorable resist pattern to be formed with superior sensitivity. Therefore, the radiation-sensitive composition and the resist pattern-forming method can be suitably used for working processes of semiconductor devices, and the like, in which miniaturization is expected to be further in progress hereafter. Hereinafter, the embodiments of the present invention will be described in detail.

### Radiation-Sensitive Composition

The radiation-sensitive composition of one embodiment of the invention contains the particles (A) and the solvent (B). The radiation-sensitive composition may contain as a favorable component, a radiation-sensitive acid generator (hereinafter, may be also referred to as “(C) acid generator” or “acid generator (C)”), and may also contain other optional component(s) within a range not leading to impairment of the effects of the present invention.

Due to containing the particles (A), the radiation-sensitive composition is superior in developability and sensitivity. Although not necessarily clarified and without wishing to be bound by any theory, the reason for achieving the effects described above due to the radiation-sensitive composition having the aforementioned constitution is inferred as in the following, for example. The particles (A) include; the component (a) being a hydrolyzation product, etc., of a metal compound; and the component (b), with the organic acid (x) and the compound (y) of the component (b) each having a molecular weight of no less than the specified value, thereby enabling the solubility of the particles (A) in the solvent (B) to be adequate, and consequently leading to favorable formation of the composition of the particles (A) and the solvent (B). In addition, the solubility of the particles (A) in the developer solution can be adequate, whereby developability of the radiation-sensitive composition is consequently improved. Furthermore, a change in the solubility of the particles (A) after exposure as compared with before the exposure can be increased, and as a result, the sensitivity of the radiation-sensitive composition is improved. Hereinafter, each component will be described.

### (A) Particles

The particles (A) include the component (a) and the component (b). The expression that “the particles include the component (a) and the component (b)” as referred to indicates a concept involving both: a case in which the component (a) and the component (b) are chemically bonded; and a case in which the component (a) and the component (b) are not chemically bonded. Examples of the chemical bond in the case of the two components being chemically bonded include a covalent bond, a coordinate bond, a hydrogen bond, and the like.

(a) Component

The component (a) is a hydrolyzation product or a hydrolytic condensation product of the metal compound (p), or a combination thereof.

(p) Metal Compound

The metal compound (p) is a metal compound having a hydrolyzable group.

The metal element included in the metal compound (p) is exemplified by metal elements from groups 3 to 16, and the like.

Examples of the metal elements from group 3 include a scandium atom, an yttrium atom, a lanthanum atom, a cerium atom and the like.

Examples of the metal elements from group 4 include a titanium atom, a zirconium atom, a hafnium atom and the like.

Examples of the metal elements from group 5 include a vanadium atom, a niobium atom, a tantalum atom and the like.

Examples of the metal elements from group 6 include a chromium atom, a molybdenum atom, a tungsten atom and the like.

Examples of the metal elements from group 7 include a manganese atom, a rhenium atom and the like.

Examples of the metal elements from group 8 include an iron atom, a ruthenium atom, an osmium atom and the like.

Examples of the metal elements from group 9 include a cobalt atom, a rhodium atom, an iridium atom and the like.

Examples of the metal elements from group 10 include a nickel atom, a palladium atom, a platinum atom and the like.

Examples of the metal elements from group 11 include a copper atom, a silver atom, a gold atom and the like.

Examples of the metal elements from group 12 include a zinc atom, a cadmium atom, a mercury atom and the like.

Examples of the metal elements from group 13 include an aluminum atom, a gallium atom, an indium atom and the like.

Examples of the metal elements from group 14 include a germanium atom, a tin atom, a lead atom and the like.

Examples of the metal elements from group 15 include an antimony atom, a bismuth atom and the like.

Examples of the metal elements from group 16 include a tellurium atom and the like.

Of these, the metal element included in the metal compound (p) is preferably a metal element from period 4 to period 7 in group 4, group 5, group 6, group 8, group 9, group 10, group 12, group 13 or group 14, and more preferably zirconium, hafnium, nickel, cobalt, tin, indium, titanium, ruthenium, tantalum, tungsten or zinc. When metal element included in the metal compound (p) is as described above, more effective promotion of the generation of the secondary electrons is enabled, whereby the sensitivity can be more improved. Moreover, contrast of rates of dissolution of the resist film at the light-exposed regions and the light-unexposed regions in the developer solution can be more improved, thereby enabling the developability to be more improved. The metal compound (p) may include one, or two or more types of the metal element.

The hydrolyzable group included in the metal compound (p) is exemplified by a halogen atom, an alkoxy group, an acyloxy group, and the like.

Examples of the halogen atom include a fluorine atom, a chlorine atom, a bromine atom, an iodine atom, and the like.

Examples of the alkoxy group include a methoxy group, an ethoxy group, a n-propoxy group, an i-propoxy group, a n-butoxy group, an i-butoxy group, a sec-butoxy group, a t-butoxy group, and the like.

Examples of the acyloxy group include a formyloxy group, an acetoxy group, a propionyloxy group, a n-butyryloxy group, a t-butyryloxy group, a t-amylyloxy group, a n-hexanecarbonyloxy group, a n-octanecarbonyloxy group, and the like.

The hydrolyzable group is preferably the halogen atom or the alkoxy group, and more preferably a chlorine atom, an ethoxy group or a t-butoxy group.

In a case in which the component (a) is the hydrolytic condensation product of the metal compound (p), the hydrolytic condensation product of the metal compound (p) may be a hydrolytic condensation product of the metal compound (p) with a compound including a metalloid atom, within a range not leading to impairment of the effects of the embodiments of the present invention. In other words, the hydrolytic condensation product of the metal compound (p) may also include a metalloid atom within a range not leading to impairment of the effects of the embodiments of the present invention. The metalloid atom is exemplified by a boron atom, arsenic atom, and the like. The percentage content of the metalloid atom in the hydrolytic condensation product of the metal compound (p) is typically less than 50 atom % with respect to the entirety of the metal atom and the metalloid atom in the hydrolytic condensation product. The upper limit of the percentage content of the metalloid atom is preferably 30 atom % and more preferably 10 atom % with respect to the entirety of the metal atom and the metalloid atom in the hydrolytic condensation product.

The metal compound (p) is exemplified by compounds represented by the following formula (A) (hereinafter, may be also referred to as a “metal compound (p-1)”), and the like. By using the metal compound (p-1), forming a stable component (a) is enabled, thereby consequently enabling the developability and sensitivity of the radiation-sensitive composition to be more improved.

LₐMY_{b} (A)

In the above formula (A), M represents the metal atom; L represents a ligand; a is an integer of 0 to 2, wherein in a case where a is 2, a plurality of Ls are identical or different; Y represents the hydrolyzable group selected from a halogen atom, an alkoxy group and an acyloxy group; and b is an integer of 2 to 6, wherein a plurality of Ys are identical or different, and L is a ligand that does not fall under the category of Y.

The metal atom represented by M is exemplified by atoms of elements exemplified as the metal elements which may be included in the metal compound (p), and the like.

The ligand represented by L is exemplified by a monodentate ligand and a polydentate ligand.

Exemplary monodentate ligand includes a hydroxo ligand, a carboxy ligand, an amide ligand, an ammonia ligand and the like.

Examples of the amido ligand include an unsubstituted amido ligand (NH₂), a methylamido ligand (NHCH₃), a dimethylamido ligand (N(CH₃)₂), a diethylamido ligand (N(C₂H₅)₂), a dipropylamido ligand (N(C₃H₇)₂), and the like.

Exemplary polydentate ligand includes a hydroxy acid ester, a β-diketone, a β-keto ester, a β-dicarboxylic acid ester, a hydrocarbon having a π bond, a diphosphine, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the β-dicarboxylic acid ester include malonic acid diesters, α-alkyl-substituted malonic acid diesters, α-cycloalkyl-substituted malonic acid diesters, α-aryl-substituted malonic acid diesters, and the like.

Examples of the hydrocarbon having a π bond include:

chain olefins such as ethylene and propylene;

cyclic olefins such as cyclopentene, cyclohexene and norbornene;

chain dienes such as butadiene and isoprene;

cyclic dienes such as cyclopentadiene, methylcyclopentadiene, pentamethylcyclopentadiene, cyclohexadiene and norbornadiene;

aromatic hydrocarbons such as benzene, toluene, xylene, hexamethylbenzene, naphthalene and indene; and the like.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, 1,1′-bis(diphenylphosphino)ferrocene, and the like.

Examples and preferred examples of the halogen atom, the alkoxy group and the acyloxy group that may be represented by Y may be similar to those explained in connection with the hydrolyzable group.

Preferably, b is 2 to 4, and more preferably 2 or 4. When b is the above specified value, it is possible to increase the percentage content of the metal atom in the component (a), whereby more effective promotion of the generation of the secondary electrons by the particles (A) is consequently enabled. Consequently, a more improvement of the sensitivity of the radiation-sensitive composition is enabled.

As the metal compound (p), a metal halide that is neither hydrolyzed nor hydrolytically condensed, or a metal alkoxide that is neither hydrolyzed nor hydrolytically condensed is preferred.

Examples of the metal compound (p) include:

zirconium-containing compounds such as zirconium(IV) chloride, zirconium(IV) n-butoxide, zirconium(IV) n-propoxide, zirconium(IV) isopropoxide, zirconium(IV) di-n-butoxide bis(2,4-pentanedionate), aminopropyltriethoxyzirconium(IV), 2-(3,4-epoxycyclohexyl)ethyltrimethoxyzirconium(IV), γ-glycidoxypropyltrimethoxyzirconium(IV), 3-isocyanopropyltrimethoxyzirconium(IV), 3-isocyanopropyltriethoxyzirconium(IV), triethoxymono(acetylacetonato)zirconium(IV), tri-n-propoxymono(acetylacetonato)zirconium(IV), tri-i-propoxymono(acetylacetonato)zirconium(IV), di-n-butoxybis(acetylacetonato)zirconium(IV), tri(3-methacryloxypropyl)methoxyzirconium(IV) and tri(3-acryloxypropyl)methoxyzirconium(IV);

hafnium-containing compounds such as hafnium(IV) chloride, hafnium(IV) ethoxide, hafnium(IV) isopropoxide and bis(cyclopentadienyl)hafnium(IV) dichloride;

titanium-containing compounds such as titanium(IV) n-butoxide, titanium(IV) n-propoxide, titanium(IV) tri-n-butoxide stearate, a titanium butoxide oligomer, aminopropyltrimethoxytitanium(IV), triethoxymono(acetylacetonato)titanium(IV), tri-n-propoxymono(acetylacetonato)titanium(IV), tri-i-propoxymono(acetylacetonato)titanium(IV), di-isopropoxybis(acetylacetonato)titanium(IV) and di-n-butoxybis(acetylacetonato)titanium(IV);

tantalum-containing compounds such as tantalum(V) ethoxide;

tungsten-containing compounds such as tungsten(V) methoxide, tungsten(VI) ethoxide, tungsten(IV) ethoxide and bis(cyclopentadienyl)tungsten(IV) dichloride;

iron-containing compounds such as iron chloride;

ruthenium-containing compounds such as diacetato[(S)-(−)-2,2′-bis(diphenylphosphino)-1,1′-binaphthyl] ruthenium(II);

cobalt-containing compounds such as dichloro[ethylenebis(diphenylphosphine)]cobalt(II);

nickel-containing compounds such as nickel(II) chloride;

zinc-containing compounds such as zinc(II) chloride, zinc(II) isopropoxide and zinc acetate dihydrate;

indium-containing compounds such as indium(III) isopropoxide;

tin-containing compounds such as tin(IV) t-butoxide and tin(IV) isopropoxide; and the like.

The metal compound (p) is preferably zirconium(IV) chloride, hafnium(IV) chloride, tungsten(IV) ethoxide, zinc(II) chloride or tin(IV) t-butoxide.

A procedure for obtaining the hydrolyzation product and/or the hydrolytic condensation product of the metal compound (p) may be exemplified by: a procedure of subjecting the metal compound (p) to a hydrolysis reaction and/or a hydrolytic condensation reaction in water, and the like. In this case, other compound having a hydrolyzable group may be added as needed. Also, the reaction may be allowed in water to which an organic solvent is added. The lower limit of the amount of the water used for the reaction with respect to the hydrolyzable group included in the metal compound (p) is preferably an equimolar amount, more preferably 10 times molar amount, and still more preferably 50 times molar amount. The upper limit of the amount of the water is preferably 1,000 times molar amount, more preferably 500 times molar amount, and still more preferably 300 times molar amount. When the amount of the water in the hydrolytic condensation reaction falls within the above range, a percentage content of the metal atom in the component (a) can be increased, thereby consequently enabling the developability and sensitivity of the radiation-sensitive composition to be more improved.

The lower limit of the temperature of the reaction is preferably 0° C., and more preferably 40° C. The upper limit of the aforementioned temperature is preferably 150° C., and more preferably 100° C.

The lower limit of the time period of the reaction is preferably 1 min, and more preferably 10 min. The upper limit of the time period is preferably 10 hrs, and more preferably 1 hour.

With respect to the reaction solution containing the component (a), the solvent used may be removed after the completion of the reaction, or the component (b) may be directly added without removing the solvent after the reaction to carry out the synthesis reaction of the particles (A).

(b) Component

The component (b) is the organic acid (x), an anion of the organic acid (x), the compound (y) or a combination thereof. The organic acid (x) and the compound (y) each have a molecular weight of no less than 120.

(x) Organic Acid

The organic acid (x) is an acidic organic compound. The organic acid (x) has a molecular weight of no less than 120.

The lower limit of the pKa of the organic acid (x) is preferably 0, more preferably 1, still more preferably 1.5, and particularly preferably 3. Meanwhile, the upper limit of the pKa is preferably 7, more preferably 6, still more preferably 5.5, and particularly preferably 5. When the pKa of the organic acid (x) falls within the above range, the interaction with the metal atom can be adjusted to be adequately weak, thereby consequently enabling the developability and sensitivity of the radiation-sensitive composition to be more improved. Herein, when the organic acid (x) is a polyvalent acid, the pKa of the organic acid (x) as referred to means a logarithm value of a first acid dissociation constant, i.e., a dissociation constant with respect to dissociation of a first proton. The pKa as referred to herein means a value generally employed as a marker indicating acid strength of a target substance. The pKa value of the organic acid (x) may be determined by measuring in accordance with a common procedure. Alternatively, a calculated value determined by using a well-known software such as “ACD/Labs” available from Advanced Chemistry Development, Inc., may be used.

The organic acid (x) may be either a low-molecular-weight compound or a high-molecular-weight compound, and in light of adjustment of the interaction with the metal atom to be adequately weak, the low-molecular-weight compound is preferred. As referred to herein, the low-molecular-weight compound means a compound having a molecular weight of no greater than 1,500, whereas the polymer compound means a compound having a molecular weight of greater than 1,500.

The organic acid (x) is exemplified by a carboxylic acid, a sulfonic acid, a sulfinic acid, an organic phosphinic acid, an organic phosphonic acid, a phenol, an enol, a thiol, an acid imide, an oxime, a sulfonamide, and the like.

Examples of the carboxylic acid include:

monocarboxylic acids such as heptanoic acid, octanoic acid, nonanoic acid, decanoic acid, 2-ethylhexanoic acid, 1-cyclohexene-1-carboxylic acid, 3-cyclohexene-1-carboxylic acid, oleic acid, stearic acid, linoleic acid, linolenic acid, arachidonic acid, salicylic acid, benzoic acid, 3,5-dihydroxybenzoic acid, p-aminobenzoic acid, dichloroacetic acid, trichloroacetic acid, pentafluoropropionic acid, gallic acid, shikimic acid, (−)-camphanic acid, 5-norbornene-2-carboxylic acid and 5-hydroxy-2,3-norbornanedicarboxylic acid γ-lactone;

dicarboxylic acids such as adipic acid, sebacic acid, phthalic acid and tartaric acid;

carboxylic acids having no less than three carboxy groups such as citric acid; and the like.

Examples of the sulfonic acid include benzenesulfonic acid, p-toluenesulfonic acid, and the like.

Examples of the sulfinic acid include benzenesulfinic acid, p-toluenesulfinic acid, and the like.

Examples of the organic phosphinic acid include methylphenylphosphinic acid, diphenylphosphinic acid, and the like.

Examples of the organic phosphonic acid include t-butylphosphonic acid, cyclohexylphosphonic acid, phenylphosphonic acid, and the like.

Examples of the phenol include:

monovalent phenols such as 2,6-xylenol and naphthol;

divalent phenols such as methylhydroquinone and 1,2-naphthalenediol;

phenols having a valency of no less than 3 such as p pyrogallol and 2,3,6-naphthalenetriol; and the like.

Examples of the enol include 3-oxo-5-hydroxy-4-heptene, 4-oxo-6-hydroxy-5-nonene, and the like.

Examples of the thiol include octanethiol, decanethiol, and the like.

Examples of the acid imide include carboxylic imides such as 3-phenylmaleimide, 3-phenylsuccinimide and di(trifluorobutanecarboxylic acid)imide;

sulfonic imides such as di(trifluorobutanesulfonic acid)imide; and the like.

Examples of the oxime include:

aldoximes such as salicylaldoxime;

ketoximes such as cyclododecanoneoxime; and the like.

Examples of the sulfonamide include benzenesulfonamide, toluenesulfonamide, and the like.

In light of more improvements of the developability and sensitivity of the radiation-sensitive composition, the organic acid (x) is preferably the carboxylic acid, and more preferably (−)-camphanic acid, 3,5-dihydroxybenzoic acid, 1-cyclohexane-1-carboxylic acid, 3-cyclohexene-1-carboxylic acid, 5-norbornene-2-carboxylic acid or a compound (hereinafter, may be also referred to as “organic acid (x-1)”) represented by the following formula (2).

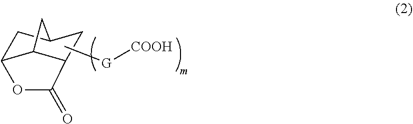

In the above formula (2), G represents a single bond or a divalent hydrocarbon group having 1 to 10 carbon atoms; and m is an integer of 1 to 10, wherein in a case in which m is no less than 2, a plurality of Gs are identical or different.

The divalent hydrocarbon group having 1 to 10 carbon atoms represented by G is exemplified by a divalent chain hydrocarbon group having 1 to 10 carbon atoms, a divalent alicyclic hydrocarbon group having 3 to 10 carbon atoms, a divalent aromatic hydrocarbon group having 6 to 10 carbon atoms, and the like.

Examples of the divalent chain hydrocarbon group having 1 to 10 carbon atoms include:

alkanediyl groups such as a methanediyl group and an ethanediyl group;

alkenediyl groups such as an ethenediyl group and a propenediyl group;

alkynediyl groups such as an ethynediyl group and a propenediyl group; and the like.

Examples of the divalent alicyclic hydrocarbon group having 3 to 10 carbon atoms include:

divalent alicyclic saturated hydrocarbon groups such as a cyclopentanediyl group, a cyclohexanediyl group and a norbornanediyl group;

divalent alicyclic unsaturated hydrocarbon groups such as a cyclopentenediyl group, a cyclohexenediyl group and a norbornenediyl group; and the like.

Examples of the divalent aromatic hydrocarbon group having 6 to 10 carbon atoms include:

arenediyl groups such as a benzenediyl group, a toluenediyl group and a naphthalenediyl group;

arenediylalkanediyl groups such as a benzenediylmethanediyl group and a benzenediylethanediyl group; and the like.

G represents preferably a single bond.

In the above formula (2), m is preferably 1 to 3, more preferably 1 or 2, and still more preferably 1.

The organic acid (x-1) is preferably 5-hydroxy-2,3-norbornanedicarboxylic acid γ-lactone.

Anion of organic acid (x)

The anion of the organic acid (x) is typically formed by transfer of a proton of an acidic group to the component (a), from the organic acid (x) used in forming the particles (A). Alternatively, the anion of the organic acid (x) may be formed through using a salt of the organic acid (x) in forming the particles (A).

(y) Compound

The compound (y) is represented by the following formula (1). The compound (y) has a molecular weight of no less than 120.

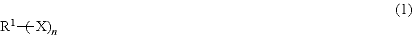

In the above formula (1), R¹ represents an organic group having a valency of n; X represents an alcoholic hydroxyl group, —NCO or —NHR^{a}, wherein R^{a} represents a hydrogen atom or a monovalent organic group; and n is an integer of 2 to 4, wherein a plurality of Xs are identical or different.

The organic group having a valency of n represented by R¹ is exemplified by a hydrocarbon group having a valency of n, a hetero atom-containing group having a valency of n in which a group having a hetero atom is included between two adjacent carbon atoms of the hydrocarbon group, a group having a valency of n in which a part or all of hydrogen atoms included in the hydrocarbon group or the hetero atom-containing group is substituted with a substituent, and the like.

Examples of the hydrocarbon group having a valency of n include groups obtained by eliminating n hydrogen atoms from hydrocarbons such as

chain hydrocarbons having 4 to 30 carbon atoms, e.g., alkanes such as butane and pentane; alkenes such as butene and pentene; and alkynes such as butyne and pentyne,

alicyclic hydrocarbons having 4 to 30 carbon atoms, e.g., cycloalkanes such as cyclobutane, cyclopentane, cyclohexane, norbomane and adamantane; and cycloalkenes such as cyclobutene, cyclopentene, cyclohexene and norbomene, and

aromatic hydrocarbons having 6 to 30 carbon atoms, e.g., arenes such as benzene, toluene, xylene, mesitylene, naphthalene, methylnaphthalene, dimethylnaphthalene and anthracene, and the like.

The hetero atom-including group is exemplified by a group that includes at least one selected from the group consisting of an oxygen atom, a nitrogen atom, a silicon atom, a phosphorus atom and a sulfur atom, and the like, and examples thereof include —O—, —NH—, —CO—, —S—, a combination thereof, and the like. Of these, —O— is preferred.

Examples of the substituent include;

halogen atoms such as a fluorine atom, a chlorine atom, a bromine atom and an iodine atom;

alkoxy groups such as a methoxy group, an ethoxy group and a propoxy group;

alkoxycarbonyl groups such as a methoxycarbonyl group and an ethoxycarbonyl group;

alkoxycarbonyloxy groups such as a methoxycarbonyloxy group and an ethoxycarbonyloxy group;

acyl groups such as a formyl group, an acetyl group, a propionyl group, a butyryl group and a benzoyl group;

a cyano group and a nitro group; and the like.

Preferably, n is 2 or 3, and more preferably 2.

The “alcoholic hydroxyl group” which may be represented by X as referred to herein means an —OH group that bonds to a saturated carbon atom in the organic group represented by R¹. The “saturated carbon atom” as referred to herein means a carbon atom not constituting a double bond, a triple bond or an aromatic ring.

The monovalent organic group which may be represented by R^{a} in —NHR^{a} is exemplified by: a monovalent hydrocarbon group having 1 to 20 carbon atoms; a hetero atom-containing group obtained from the hydrocarbon group by incorporating a hetero atom-including group between adjacent two carbons thereof; a group obtained by substituting a part or all of hydrogen atoms included in the hydrocarbon group or the hetero atom-containing group with a substituent; and the like. R^{a} represents preferably a monovalent hydrocarbon group, more preferably a monovalent chain hydrocarbon group, still more preferably an alkyl group, and particularly preferably a methyl group.

When n is 2, R¹ represents preferably a divalent chain hydrocarbon group, a divalent aromatic hydrocarbon group or a divalent hetero atom-containing group, more preferably an alkanediyl group, an alkenediyl group, an arenediyl group or an alkanediyloxyalkanediyl group, and still more preferably an octanediyl group, an octenediyl group, a xylene diyl group or a butanediyloxybutanediyl group.

When n is 3, R¹ represents preferably a trivalent chain hydrocarbon group, more preferably an alkanetriyl group, and still more preferably a 1,2,3-hexanetriyl group.

When n is 4, R¹ represents preferably a tetravalent chain hydrocarbon group, more preferably an alkanetetrayl group, and still more preferably a 1,2,3,4-butanetetrayl group.

Examples of the compound (y) include compounds represented by the following formulae (1-1) to (1-3) (hereinafter, may be also referred to as “compounds (1-1) to (1-3)”), and the like.

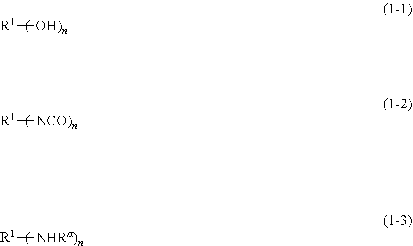

In the above formulae (1-1) to (1-3), R′, R^{a} and n are as defined in the above formula (1).

When n is 2, examples of the compound (1-1) include:

alkylene glycols such as octanediol and decanediol;

dialkylene glycols such as dibutylene glycol and tripropylene glycol;

cycloalkylene glycols such as cyclooctanediol, cyclohexanedimethanol, norbomanedimethanol and adamantanediol;

aromatic ring-containing glycols such as 1,4-benzenedimethanol and 2,6-naphthalenedimethanol;

dihydric phenols such as methylhydroquinone; and the like.

When n is 3, examples of the compound (1-1) include:

alkanetriols such as 1,2,3-octanetriol;

cycloalkanetriols such as 1,2,3-cyclooctanetriol and 1,2,3-cyclooctanetrimethanol;

aromatic ring-containing glycols such as 1,2,4-benzenetrimethanol and 2,3,6-naphthalenetrimethanol;

trihydric phenols such as pyrogallol and 2,3,6-naphthalenetriol; and the like,

When n is 4, examples of the compound (1-1) include:

alkanetetraols such as erythritol and pentaerythritol;

cycloalkanetetraols such as 1,2,4,5-cyclohexanetetraol;

aromatic ring-containing tetraols such as 1,2,4,5-benzenetetramethanol;

tetrahydric phenols such as 1,2,4,5-benzenetetraol; and the like.

Of these, the compound (1-1) wherein n is 2 or 3 is preferred, alkylene glycol, dialkylene glycol or alkanetriol is more preferred, and octanediol, dibutylene glycol or 1,2,3-octanetriol is still more preferred.

When n is 2, examples of the compound (1-2) include:

chain diisocyanates such as trimethylene diisocyanate, tetramethylene diisocyanate and hexamethylene diisocyanate;

alicyclic diisocyanates such as 1,4-cyclohexane diisocyanate and isophorone diisocyanate;

aromatic diisocyanates such as tolylene diisocyanate, 1,4-benzene diisocyanate and 4,4′-diphenylmethane diisocyanate; and the like.

When n is 3, examples of the compound (1-2) include:

chain triisocyanates such as trimethylene triisocyanate;

alicyclic triisocyanates such as 1,2,4-cyclohexane triisocyanate;

aromatic triisocyanates such as 1,2,4-benzene triisocyanate; and the like.

When n is 4, examples of the compound (1-2) include:

chain tetraisocyanates such as tetramethylene tetraisocyanate;

alicyclic tetraisocyanates such as 1,2,4,5-cyclohexane tetraisocyanate;

aromatic tetraisocyanates such as 1,2,4,5-benzene tetraisocyanate; and the like.

Of these, the compound (1-2) wherein n is 2 is preferred, a chain diisocyanate is more preferred, and hexamethylene diisocyanate is still more preferred.

When n is 2, examples of the compound (1-3) include:

chain diamines such as octamethylenediamine and decamethylenediamine;

alicyclic diamines such as cyclooctanediamine and di(aminomethyl)cyclooctane;

aromatic diamines such as 1,4-diamino-2,5-dimethylbenzene and 4,4′-diaminodiphenyl methane; and the like,

When n is 3, examples of the compound (1-3) include:

chain triamines such as triaminooctane and triaminodecane;

alicyclic triamines such as 1,2,4-triaminocyclohexane;

aromatic triamines such as 1,2,4-triaminobenzene; and the like.

When n is 4, examples of the compound (1-3) include:

chain tetraamines such as tetraaminohexane;

alicyclic tetraamines such as 1,2,4,5-tetraaminocyclohexane and 2,3,5,6-tetraaminonorbornane;

aromatic tetraamines such as 1,2,4,5-tetraaminobenzene; and the like.

Of these, the compound (1-3) wherein n is 2 is preferred, the chain diamine is more preferred, and diaminooctane is still more preferred.

It is preferred that the organic acid (x) and the compound (y) each have an alicyclic structure having 5 to 12 carbon atoms, or an aliphatic heterocyclic structure having 3 to 20 ring atoms that includes an oxygen atom, a sulfur atom and/or a nitrogen atom in the ring. When the organic acid (x) and the compound (y) each have the structure described above, the solubility of the particles (A) can be more adequate, whereby the developability and sensitivity of the radiation-sensitive composition can be more improved.

The component (b) is preferably the organic acid (x) or the anion of the organic acid (x), and more preferably the organic acid (x).

The lower limit of the molecular weight of the organic acid (x) and compound (y) is typically 120, preferably 122, more preferably 124, still more preferably 126, particularly preferably 130, more particularly preferably 150, still more particularly preferably 170, and most preferably 190. The upper limit of the molecular weight is, for example, 400, and preferably 300. When the molecular weight of the organic acid (x) and compound (y) falls within the above range, the solubility of the particles (A) can be more adequate, whereby the developability and sensitivity of the radiation-sensitive composition can be more improved.

The lower limit of the Ohnishi parameters of the organic acid (x) and compound (y) is preferably 4, more preferably 5, still more preferably 6, and particularly preferably 7. The upper limit of the Ohnishi parameters is preferably 20, more preferably 18, still more preferably 16, and particularly preferably 14. When the Ohnishi parameters of the organic acid (x) and compound (y) fall within the above range, the solubility of the particles (A) can be more adequate, whereby the developability of the radiation-sensitive composition can be more improved.

The term “Ohnishi parameter” as referred to herein means a value calculated according to an arithmetic expression of: (total atom number in a compound)/((number of carbon atom in the compound)−(number of oxygen atom in the compound)).

The hydrodynamic radius of the particles (A) as determined by a dynamic light-scattering analysis is preferably less than 20 nm, more preferably no greater than 15 nm, still more preferably no greater than 10 nm, and particularly preferably no greater than 5 nm. Meanwhile, the hydrodynamic radius is preferably no less than 1.0 nm, more preferably no less than 1.5 nm, still more preferably no less than 2.0 nm, and particularly preferably no less than 2.5 nm. When the hydrodynamic radius of the particles (A) falls within the above range, the sensitivity of the radiation-sensitive composition can be more improved. The “hydrodynamic radius” means a harmonic mean particle diameter on the basis of scattered light intensity, as measured by DLS (Dynamic Light Scattering) using a light scattering measurement device.

In the particles (A), it is preferred that the organic acid (x) or the anion of the organic acid (x), the compound (y), or a combination thereof is coordinated to one or a plurality of metal atoms in the hydrolyzation product or the hydrolytic condensation product of the metal compound (p) or a combination thereof. When the particles (A) have the aforementioned coordination structure, the solubility of the particles (A) in the solvent (B) can be more adequate, thereby consequently enabling the developability and sensitivity of the radiation-sensitive composition to be more improved.

The lower limit of the proportion of the particles (A) contained with respect to the total solid content of the radiation-sensitive composition is preferably 80 mass %, and more preferably 85 mass %. The upper limit of the content of the particles (A) is, for example, 100 mass %. The term “total solid content” as referred to herein means the sum of components other than the solvent (B) in the radiation-sensitive composition.

### Synthesis Procedure of Particles (A)

The particles (A) may be obtained by mixing the component (a) and the component (b). More specifically, the particles (A) can be synthesized by adding the organic acid (x), the anion of the organic acid (x), the compound (y) or a combination thereof as the component (b), to a reaction liquid containing the component (a) obtained by a hydrolysis reaction and/or a hydrolytic condensation reaction of the metal compound (p).

### (B) Solvent

The solvent (B) is not particularly limited as long as it is a solvent capable of dissolving or dispersing at least particles (A), and the acid generator (C), etc., included as needed.

The solvent (B) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as propylene glycol;

C3-19 polyhydric alcohol partial ether solvents such as propylene glycol monomethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydropyran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-dicthylformamide, acetamide, N-methylacetamide, N,N-dimethylacetami de and N-methylpropionamide; and the like.

Examples of the ester solvent include:

monocarboxylic acid ester solvents such as n-butyl acetate and ethyl propionate;

hydroxycarboxylic acid ester solvents such as ethyl lactate and n-butyl glycolate;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

lactone solvents such as γ-butyrolactone and δ-valerolactone;

carbonate solvents such as dimethyl carbonate, diethyl carbonate, ethylene carbonate and propylene carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

As the solvent (B), the ester solvents are preferred, the polyhydric alcohol partial ether carboxylate solvents are more preferred, and propylene glycol monomethyl ether acetate is still more preferred. The radiation-sensitive composition may contain one, or two or more types of the solvent (B).

### (C) Acid Generator

The radiation-sensitive composition may contain the acid generator (C). The acid generator (C) is a compound that is capable of generating an acid by light or heat. When the radiation-sensitive composition further contains the acid generator (C), the developability can be more improved. In the radiation-sensitive composition, the acid generator (C) may be contained in the form of a low-molecular-weight compound (hereinafter, may be also referred to as “(C) acid generating agent” or “acid generating agent (C)”), in the form incorporated as a part of the particles (A), or may be in both of these forms.

The acid generating agent (C) is exemplified by an onium salt compound, an N-sulfonyloxyimide compound, and the like. As the acid generator (C), a thermal acid generator that is capable of generating an acid by heat is preferred, and in particular, an onium salt compound is preferred.

The onium salt compound is exemplified by a sulfonium salt, a tetrahydrothiophenium salt, an iodonium salt, an ammonium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, 4-cyclohexylphenyldiphenylsulfonium trifluoromethanesulfonate, and the like.

Examples of the tetrahydrothiophenium salt include 1-(4-n-butoxynaphthalen-1-yetetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, and the like.

Examples of the ammonium salt include ammonium formate, ammonium maleate, ammonium fumarate, ammonium benzoate, ammonium p-aminobenzoate, ammonium p-toluenesulfonate, ammonium methanesulfonate, ammonium trifluoromethanesulfonate, ammonium trifluoroethanesulfonate, and the like.

Examples of the N-sulfonyloxyimide compound include N-(trifluoromethanesulfonyloxy)bicyclo[2.2.1]hept-5-ene-2,3-dicarboxyimide, N-(nonafluoro-n-butanesulfonyloxy)bicyclo[2.2.1]hept-5-ene-2,3-dicarboxyimide, and the like.

As the acid generating agent (C), the onium salt compound is preferred, the sulfonium salt is more preferred, a triphenylsulfonium salt is still more preferred, and triphenylsulfonium trifluoromethanesulfonate is particularly preferred.

In the case in which the radiation-sensitive composition contains the acid generating agent (C), the lower limit of the content of the acid generating agent (C) with respect to 100 parts by mass of the particles (A) is preferably 0.1 parts by mass, more preferably 1 part by mass, and still more preferably 5 parts by mass. The upper limit of the content of the acid generating agent (C) is preferably 100 parts by mass, more preferably 50 parts by mass, and still more preferably 20 parts by mass. When the content of the acid generating agent (C) falls within the above range, the developability and sensitivity of the radiation-sensitive composition can be further improved. The radiation-sensitive composition may contain one, or two or more types of the acid generator (C).

### Other Optional Component

The other optional component is exemplified by a surfactant, and the like.

### Preparation Procedure of Radiation-Sensitive Resin Composition

The radiation-sensitive composition may be prepared, for example, by mixing the particles (A) and the solvent (B), as well as if necessary, the optional component such as the acid generator (C) at a certain ratio, preferably followed by filtering a resultant mixture through a filter having a pore size of no greater than 0.2 μm. The lower limit of the solid content concentration of the radiation-sensitive composition is preferably 0.1% by mass, more preferably 0.5% by mass, still more preferably 1% by mass, and particularly preferably 3% by mass. The upper limit of the solid content concentration is preferably 50% by mass, more preferably 30% by mass, still more preferably 15% by mass, and particularly preferably 7% by mass.

### Resist Pattern-Forming Method

The resist pattern-forming method of the other embodiment of the invention includes the steps of: applying the radiation-sensitive composition of the one embodiment of the invention directly or indirectly on at least one face side of a substrate (hereinafter, may be also referred to as “applying step”); exposing a resist film formed by the applying step (hereinafter, may be also referred to as “exposure step”); developing the resist film exposed (hereinafter, may be also referred to as “development step”).

The resist pattern-forming method enables a favorable resist pattern to be formed with superior sensitivity since the radiation-sensitive composition described above is used. Hereinafter, each step will be described.

Applying Step

In this step, the radiation-sensitive composition is directly or indirectly applied on at least one face side of a substrate. Examples of the substrate include a silicon wafer, a wafer coated with aluminum, and the like. A procedure for applying the radiation-sensitive composition is not particularly limited, and a well-known procedure such as, e.g., spin coating, or the like may be employed. Upon applying the radiation-sensitive composition, the amount of the radiation-sensitive composition applied is adjusted such that the resist film to be formed has a desired thickness. It is to be noted that after the applying of the radiation-sensitive composition on the substrate, prebaking (PB) may be carried out for allowing the solvent to be volatilized. The lower limit of the temperature of PB is preferably 30° C., and more preferably 50° C. The upper limit of the temperature is preferably 200° C., and more preferably 150° C. The lower limit of the time period of PB is preferably 10 sec, and more preferably 30 sec. The upper limit of the time period is preferably 600 sec, and more preferably 300 sec. The lower limit of the average thickness of the resist film is preferably 10 nm, more preferably 20 nm, and still more preferably 30 nm. The upper limit of the average thickness of the resist film is preferably 1,000 nm, more preferably 200 nm, and still more preferably 100 nm. Accordingly, the resist film is formed.

Exposure Step

In this step, the resist film formed by the applying step is exposed. The exposure is carried out by irradiation with a radioactive ray through a mask having a predetermined pattern via a liquid immersion medium such as water, as the case may be.

As the liquid for liquid immersion lithography, a liquid having a refractive index greater than that of the air is typically used. Specifically, pure water, a long chain or a cyclic aliphatic compound, and the like may be exemplified. The resist film is irradiated with the radioactive ray emitted from a lithography device through the liquid for liquid immersion lithography, i.e., with a space between a lens and the resist film being filled with the liquid for liquid immersion lithography, whereby the resist film is exposed through a mask having a predetermined pattern.

The radioactive ray employed may be appropriately selected in accordance with the type of the radiation-sensitive acid generator used, from among electromagnetic waves e.g., visible light rays, ultraviolet rays, far ultraviolet rays such as an ArF excimer laser beam (wavelength: 193 nm) and a KrF excimer laser beam (wavelength: 248 nm), extreme ultraviolet rays (EUV; 13.5 nm), X-rays, etc., and charged particle rays such as an electron beam and an α-ray, and the like. Of these, an ArF excimer laser beam, a KrF excimer laser beam, EUV, X-ray or an electron beam is preferred, an ArF excimer laser beam, EUV or an electron beam is more preferred, and EUV or an electron beam is still more preferred. It is to be noted that exposure conditions such as an exposure dose may be appropriately selected in accordance with the blend composition of the radiation-sensitive composition, the type of an additive, and the like.

The resist film exposed is preferably subjected to a baking treatment (hereinafter, may be also referred to as “post exposure baking (PEB)”). The PEB enables a modification reaction, etc., of the particles (A) to smoothly proceed. The baking conditions for the PEB may be appropriately adjusted in accordance with the blend formulation of the radiation-sensitive composition, and the lower limit of the temperature of PEB is preferably 30° C., more preferably 50° C., and still more preferably 80° C. The upper limit of the temperature of PEB is preferably 250° C., more preferably 200° C., still more preferably 180° C., and particularly preferably 160° C. When the temperature of PEB is no less than the lower limit, the developability of the radiation-sensitive composition can be more improved. When the temperature of PEB is no greater than the upper limit, the sensitivity of the radiation-sensitive composition can be more improved. The lower limit of the time period of PEB is preferably 10 sec, and more preferably 30 sec. The upper limit of the time period is preferably 600 sec, and more preferably 300 sec.

Additionally, in order to maximally utilize the potential of the radiation-sensitive composition, an organic or inorganic antireflective film may also be formed on the substrate employed, as disclosed in, for example, Japanese Examined Patent Application, Publication No. H6-12452, Japanese Unexamined Patent Application, Publication No. S59-93448, and the like. Moreover, in order to avoid the influence of basic impurities and the like contained in an environment atmosphere, a protective film may be provided on the resist film, as disclosed in, for example, Japanese Unexamined Patent Application, Publication No. H5-188598, and the like.

Development Step

In this step, the resist film exposed in the exposure step is developed. The developer solution for use in this development is exemplified by an alkaline aqueous solution (alkaline developer solution), an organic solvent-containing liquid (organic solvent developer solution), and the like. Thus, a predetermined resist pattern is formed.

The aqueous alkali solution is exemplified by aqueous solutions prepared by dissolving at least one alkaline compound such as sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, etc., and the like. Of these, an aqueous TMAH solution is preferred, and a 2.38% by mass aqueous TMAH solution is more preferred.

The organic solvent-containing liquid is exemplified by organic solvents such as the hydrocarbon solvent, the ether solvent, the ester solvent, the ketone solvent and the alcohol solvent, or the liquid containing an organic solvent. Examples of the organic solvent include one type, or two or more types of the solvents exemplified in connection with the solvent (B) of the aforementioned radiation-sensitive composition, and the like. Of these, the ester solvent and the ketone solvent are preferred. As the ester solvent, an acetic acid ester solvent is preferred, and n-butyl acetate is more preferred. As the ketone solvent, a chain ketone is preferred, and 2-heptanone is more preferred. The lower limit of the content of the organic solvent in the organic solvent-containing liquid is preferably 80% by mass, more preferably 90% by mass, still more preferably 95% by mass, and particularly preferably 99% by mass. Components other than the organic solvent in the organic solvent-containing liquid are exemplified by water, silicone oil, and the like.

As the developer solution, the organic solvent-containing liquid is preferred, the hydrocarbon solvent, the ketone solvent, the alcohol solvent or the ester solvent is more preferred, and hexane, 2-heptanone, methanol, 2-propanol or butyl acetate is still more preferred.

These developer solutions may be used either alone, or in combination of two or more types thereof. It is to be noted that washing with water or the like, followed by drying, is generally carried out after the development.

### EXAMPLES

Hereinafter, the present invention is explained in detail by way of Examples, but the present invention is not in any way limited to these Examples. It is to be noted that for the DLS analysis, the particles (A) were dissolved in propylene glycol monomethyl ether acetate to prepare a 3% by mass solution, which was then subjected to the measurement.

### Synthesis of Particles (A)

### Synthesis Example 1

Into a reaction vessel, 3 mmol of zirconium(IV) chloride was charged, and thereto was added 25 g of water dropwise over 15 min while the vessel was cooled with ice water. During the dropwise addition, the internal temperature was adjusted so as not to exceed 80° C. owing to heat generation throughout the reaction. After completion of the dropwise addition, the mixture was ascertained to be a transparent aqueous solution, and thereto were added 125 g of water and 21 mmol of (−)-camphanic acid (molecular weight: 198; and Ohnishi parameter: 4.67) in an ice-cooled state. Next, the reaction solution was heated to an internal temperature of 65° C. and stirred at this temperature for 6 hrs. During the heating, white particles were produced in the solution. Further, the mixture was stirred at an internal temperature of 80° C. for 10 hrs. Thereafter, the mixture was filtered while being heated to collect the white particles, and the particles were washed with water three times. After the washing, the particles were dried under reduced pressure at 25° C. for 12 hrs to give particles (P-1) with a favorable yield. As a result of a proton NMR analysis, the particles were ascertained to have (−)-camphanic acid as a ligand, and as a result of a fluorescent X-ray analysis, the particles were also ascertained to include zirconium. The particle diameter of the particles as determined by the DLS analysis was revealed to involve a distribution of the average particle diameter being 2.0 nm, and a distribution of the average particle diameter being 90.5 nm, with the area ratios of the former being 20% and the latter being 80%.

### Synthesis Example 2

Into a reaction vessel, 3 mmol of zirconium(IV) chloride was charged, and thereto was added 25 g of water dropwise over 15 min while the vessel was cooled with ice water. During the dropwise addition, the internal temperature was adjusted so as not to exceed 80° C. owing to heat generation throughout the reaction. After completion of the dropwise addition, the mixture was ascertained to be a transparent aqueous solution, and thereto were added 125 g of water and 9 mmol of (−)-camphanic acid (molecular weight: 198; and Ohnishi parameter: 4.67) in an ice-cooled state. Next, the reaction solution was heated to an internal temperature of 65° C. and stirred at this temperature for 6 hrs. During the heating, white particles were produced in the solution. Thereafter, the mixture was filtered while being heated to collect the white particles, and the particles were washed with water three times. After the washing, the particles were dried under reduced pressure at 25° C. for 12 hrs to give particles (P-2) with a favorable yield. As a result of a proton NMR analysis, the particles were ascertained to have (−)-camphanic acid as a ligand, and as a result of a fluorescent X-ray analysis, the particles were also ascertained to include zirconium. The particle diameter of the particles as determined by the DLS analysis was revealed to involve only a distribution of the average particle diameter being 3.0 nm, with a presence ratio (area ratio) for the particle diameter greater than 20 nm being less than 1%.

### Synthesis Example 3

Into a reaction vessel, 3 mmol of zirconium(IV) chloride was charged, and thereto was added 25 g of water dropwise over 15 min while the vessel was cooled with ice water. During the dropwise addition, the internal temperature was adjusted so as not to exceed 80° C. owing to heat generation throughout the reaction. After completion of the dropwise addition, the mixture was ascertained to be a transparent aqueous solution, and thereto were added 125 g of water and 21 mmol of methacrylic acid (molecular weight: 86; and Ohnishi parameter: 6.00) in an ice-cooled state. Next, the reaction solution was heated to an internal temperature of 65° C. and stirred at this temperature for 6 hrs. Further, the reaction solution was stirred at an internal temperature of 80° C. for 10 hrs. During the heating at 80° C., white particles were produced in the solution. Thereafter, the mixture was filtered while being heated to collect the white particles, and the particles were washed with water three times. After the washing, the particles were dried under reduced pressure at 25° C. for 12 hrs to give particles (P-3) with a favorable yield. As a result of a proton NMR analysis, the particles were ascertained to have methacrylic acid as a ligand, and as a result of a fluorescent X-ray analysis, the particles were also ascertained to include zirconium. The particle diameter of the particles as determined by the DLS analysis was revealed to involve only a distribution of the average particle diameter being 1.8 nm, with a presence ratio (area ratio) for the particle diameter greater than 20 nm being less than 1%.

### Synthesis Examples 4 to 13

The particles (A) were synthesized in a similar manner to Synthesis Examples 1 to 3 except that the type and the amount of each of the metal compound (p) and the compound of the component (b) as basic ingredients for the synthesis were as shown in Table 1 below. It is to be noted that denotations of “-” in the column of particles (A), and “no particles produced” in the column of “DLS analysis of produced particles” indicate that production of the particles was not found in the synthesis reaction of the particles, whereby collection of the particles failed. Further, the denotation “insoluble in organic solvent” indicates that although the particles were successfully produced and collected, it was impossible to perform the analysis since the particles were insoluble in the organic solvent. In Synthesis Example 6, “∞” for the Ohnishi parameter indicates that (carbon atom number)−(oxygen atom number) in acetic acid (i.e., denominator in the equation for calculating the Ohnishi parameter) was zero.

TABLE 1

| | | | | (b) Component | | |
|---|---|---|---|---|---|---|
| | (A) | (p) Metal compound | | | molecular | Ohnishi |
| | Particles | type | amount | type | weight | parameter |
| Synthesis Example 1 | P-1 | zirconium(IV) | 3 mmol | (−)-camphanic acid | 198 | 4.67 |
| | | chloride | | | | |
| Synthesis Example 2 | P-2 | zirconium(IV) | 3 mmol | (−)-camphanic acid | 198 | 4.67 |
| | | chloride | | | | |
| Synthesis Example 3 | P-3 | zirconium(IV) | 3 mmol | methacrylic acid | 86 | 6 |
| | | chloride | | | | |
| Synthesis Example 4 | P-4 | hafnium(IV) | 3 mmol | 3,5-dihydroxybenzoic | 154 | 5.67 |
| | | chloride | | acid | | |
| Synthesis Example 5 | P-5 | hafnium(IV) | 3 mmol | 3-cyclohexene-1- | 126 | 3.8 |
| | | chloride | | carboxylic acid | | |
| Synthesis Example 6 | — | hafnium(IV) | 3 mmol | acetic acid | 60 | ∞ |
| | | chloride | | | | |
| Synthesis Example 7 | P-7 | hafnium(IV) | 3 mmol | pivalic acid | 102 | 3.25 |
| | | chloride | | | | |
| Synthesis Example 8 | P-8 | zinc(II) | 3 mmol | 5-hydroxy-2,3- | 182 | 4.6 |
| | | chloride | | norbornanedicarboxylic | | |
| | | | | acid gamma-lactone | | |
| | | | | (CAS: 5411-71-2) | | |
| Synthesis Example 9 | — | zinc(II) | 3 mmol | tiglic acid | 114 | 4.5 |
| | | chloride | | | | |
| Synthesis Example 10 | P-10 | tin(IV) t- | 3 mmol | 5-norbornene-2- | 138 | 3.3 |
| | | butoxide | | carboxylic acid | | |
| Synthesis Example 11 | — | tin(IV) t- | 3 mmol | isobutyric acid | 88 | 7 |
| | | butoxide | | | | |
| Synthesis Example 12 | P-12 | tungsten(IV) | 3 mmol | 1-cyclohexene-1- | 126 | 3.8 |
| | | ethoxide | | carboxylic acid | | |
| Synthesis Example 13 | P-13 | tungsten(IV) | 3 mmol | angelic acid | 114 | 4.5 |
| | | ethoxide | | | | |

| | (b) Component | | DLS analysis of |
|---|---|---|---|
| | amount | Heating condition | produced particles |
| Synthesis Example 1 | 21 mmol | 65° C., 6 hrs → 80° C., 10 hrs | 2.0 nm (20%), 90.5 nm |
| | | | (80%) |
| Synthesis Example 2 | 9 mmol | 65° C., 6 hrs | 3.0 nm (100%) |
| Synthesis Example 3 | 21 mmol | 65° C., 6 hrs → 80° C., 10 hrs | 1.8 nm (100%) |
| Synthesis Example 4 | 21 mmol | 65° C., 6 hrs → 80° C., 10 hrs | 1.6 nm (100%) |
| Synthesis Example 5 | 21 mmol | 65° C., 6 hrs → 80° C., 10 hrs | 2.4 nm (100%) |
| Synthesis Example 6 | 21 mmol | 65° C., 6 hrs → 80° C., 10 hrs | no particles produced |
| Synthesis Example 7 | 21 mmol | 65° C., 6 hrs → 80° C., 10 hrs | insoluble in organic |
| | | | solvent |
| Synthesis Example 8 | 9 mmol | 65° C., 6 hrs | 3.0 nm (100%) |
| Synthesis Example 9 | 9 mmol | 65° C., 6 hrs | no particles produced |
| Synthesis Example 10 | 12 mmol | 65° C., 6 hrs → 80° C., 10 hrs | 2.5 nm (100%) |
| Synthesis Example 11 | 12 mmol | 65° C., 6 hrs → 80° C., 10 hrs | no particles produced |
| Synthesis Example 12 | 12 mmol | 65° C., 10 hrs | 3.6 nm (100%) |
| Synthesis Example 13 | 12 mmol | 65° C., 10 hrs | 2.4 nm (100%) |

### Preparation of Radiation-Sensitive Composition

The solvent (B) and the acid generating agent (C) used in preparing the radiation-sensitive composition are as shown below.

### (B) Solvent

B-1: propylene glycol monomethyl ether acetate

### (C) Acid Generating Agent

C-1: triphenylsulfonium trifluoromethanesulfonate

### Example 1

A radiation-sensitive composition (S-1) was prepared by dissolving 100 parts by mass of (P-1) as the particles (A) in 2,400 parts by mass of (B-1) as the solvent (B), and filtering a solution thus obtained, through a membrane filter having a pore size of 0.20 μm.

### Examples 2 to 8 and Comparative Examples 1 and 2

Radiation-sensitive compositions (S-2) to (S-10) were prepared in a similar manner to Example 1 except that the type and the content of each component used were as shown in Table 2 below. In Table 2 “-” denotes that a corresponding component was not used.

TABLE 2

| | | | | | | (C) Acid generating | |
|---|---|---|---|---|---|---|---|
| | | (A) Particles | | (B) Solvent | | agent | |
| | Radiation- | | content | | content | | content |
| | sensitive | | (parts by | | (parts by | | (parts by |
| | composition | type | mass) | type | mass) | type | mass) |
| Example 1 | S-1 | P-1 | 100 | B-1 | 2,400 | — | — |
| Example 2 | S-2 | P-2 | 100 | B-1 | 2,400 | — | — |
| Example 3 | S-3 | P-2 | 100 | B-1 | 2,400 | C-1 | 10 |
| Comparative | S-4 | P-3 | 100 | B-1 | 2,400 | — | — |
| Example 1 | | | | | | | |
| Example 4 | S-5 | P-4 | 100 | B-1 | 2,400 | — | — |
| Example 5 | S-6 | P-5 | 100 | B-1 | 2,400 | — | — |
| Example 6 | S-7 | P-8 | 100 | B-1 | 2,400 | — | — |
| Example 7 | S-8 | P-10 | 100 | B-1 | 2,400 | — | — |
| Example 8 | S-9 | P-12 | 100 | B-1 | 2,400 | — | — |
| Comparative | S-10 | P-13 | 100 | B-1 | 2,400 | — | — |
| Example 2 | | | | | | | |

### Formation of Resist Pattern

### Examples 1 to 8 and Comparative Examples 1 and 2

After each radiation-sensitive composition prepared as described above was spin-coated on a silicon wafer in “CLEAN TRACK ACT-8” available from Tokyo Electron Limited, PB was carried out under a condition at 90° C. for 60 sec to form a resist film having an average thickness of 50 nm. Next, patterning was executed by irradiating the resist film with an electron beam using a simplified electron beam writer (“HL800D” available from Hitachi, Ltd., power: 50 KeV; and electric current density: 5.0 A/cm²). In the patterning procedure, an operation of irradiating a square region having an edge length of 0.5 cm with a predetermined exposure dose with every 10 μm/cm² from 10 μC/cm² to 400 μC/cm² at 40 points in total.

After the irradiation with the electron beam, PEB was conducted in the CLEAN TRACK ACT-8 at 90° C. or 170° C. for 60 sec, and then development was carried out according to a puddle procedure by using the organic solvent shown in Table 3 below at 23° C. for 1 min in the CLEAN TRACK ACT-8 to form a negative-tone resist pattern.

### Evaluations

With respect to the resist pattern thus formed, the developability and the sensitivity of the radiation-sensitive compositions were evaluated through determination by the following procedures. The results of the evaluations are shown together in Table 3.

Developability

In accordance with the average thickness after the development at light-unexposed regions in the resist pattern formed, the developability was evaluated to be: “A” (favorable) in the case of the average thickness being less than 5 mm; and “B” (unfavorable) in the case of the average thickness being no less than 5 nm.

Sensitivity

In accordance with the amount of irradiation when the film thickness at the light-exposed region was greater than 40 nm, the sensitivity was evaluated based on the amount of the irradiation to be: “AA” (very favorable) in the case of being less than 100 μC/cm²; “A” (favorable) in the case of being no less than 100 μC/cm² and less than 400 μC/cm²; and “B” (unfavorable) in the case of being no less than 400 μC/cm².

TABLE 3

| | Radiation- | | Developability | | Sensitivity | |
|---|---|---|---|---|---|---|
| | sensitive | Developer | PEB | PEB | PEB | PEB |
| | composition | solution | 90° C. | 170° C. | 90° C. | 170° C. |
| Example 1 | S-1 | 2-heptanone | A | A | B | A |
| Example 2 | S-2 | 2-heptanone | A | B | AA | AA |
| Example 3 | S-3 | 2-heptanone | A | A | AA | AA |
| Comparative | S-4 | 2-heptanone | B | B | AA | AA |
| Example 1 | | | | | | |
| Example 4 | S-5 | methanol | A | A | A | A |
| Example 5 | S-6 | methanol | A | B | A | AA |
| Example 6 | S-7 | hexane | A | A | A | A |
| Example 7 | S-8 | 2-propanol | A | A | A | A |
| Example 8 | S-9 | 2-heptanone | A | A | A | AA |
| Comparative | S-10 | 2-heptanone | B | B | A | AA |
| Example 2 | | | | | | |

From the results shown in Table 3, it is revealed that the radiation-sensitive compositions of Examples are superior in the developability and the sensitivity. In the present Examples, the electron beam was used for the exposure of the resist film; however, also in a case of using a radioactive ray of a short wavelength such as EUV, basic resist characteristics are known to be similar to resist characteristics of the electron beam, and a correlation between those characteristics is also known. Therefore, it is expected that also in the case of an exposure with EUV, the radiation-sensitive composition would be superior in developability and sensitivity.

The radiation-sensitive composition of the one embodiment of the present invention is superior in developability and sensitivity. The resist pattern-forming method of the other embodiment of the present invention enables a favorable resist pattern to be formed with superior sensitivity. Therefore, the radiation-sensitive composition and the resist pattern-forming method can be suitably used for working processes of semiconductor devices and the like, in which microfabrication is expected to be further in progress hereafter.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive composition comprising particles and a solvent,
wherein the particles comprise a first component and a second component,
the first component is a hydrolyzation product or a hydrolytic condensation product of a metal compound comprising a hydrolyzable group, or a combination thereof; and
the second component is an organic acid, an anion of the organic acid, a first compound represented by formula (1), or a combination thereof, and
wherein
the organic acid and the first compound each have a molecular weight of no less than 120, 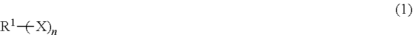
wherein, in the formula (1), R¹ represents an organic group having a valency of n; X represents an alcoholic hydroxyl group, —NCO or —NHR^{a}, wherein R^{a} represents a hydrogen atom or a monovalent organic group; and n is an integer of 2 to 4, wherein a plurality of Xs are identical or different.

2. The radiation-sensitive composition according to claim 1, wherein the second component is the organic acid, the anion of the organic acid, or a combination thereof.

3. The radiation-sensitive composition according to claim 1, wherein the organic acid and the first compound each have an Ohnishi parameter of no less than 4 and no greater than 20.

4. The radiation-sensitive composition according to claim 1, wherein the organic acid is a carboxylic acid.

5. The radiation-sensitive composition according to claim 4, wherein the organic acid is represented by formula (2): 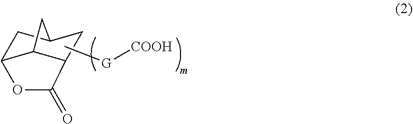
wherein, in the formula (2), G represents a single bond or a divalent hydrocarbon group having 1 to 10 carbon atoms; and m is an integer of 1 to 10, wherein in a case in which m is no less than 2, a plurality of Gs are identical or different.

6. The radiation-sensitive composition according to claim 1, wherein a metal element constituting the metal compound comprises zirconium, hafnium, nickel, cobalt, tin, indium, titanium, ruthenium, tantalum, tungsten, zinc or a combination thereof.

7. The radiation-sensitive composition according to claim 1, wherein a hydrodynamic radius of the particles as determined by a dynamic light-scattering analysis is less than 20 nm.

8. The radiation-sensitive composition according to claim 1, further comprising a radiation-sensitive acid generator.

9. The radiation-sensitive composition according to claim 1, wherein the second component is coordinated to one or a plurality of metal atoms in the first compound.

10. A resist pattern-forming method comprising:
applying the radiation-sensitive composition according to claim 1, directly or indirectly on at least one face side of a substrate to form a resist film;
exposing the resist film; and
developing the resist film exposed.

11. The resist pattern-forming method according to claim 10, wherein a developer solution used in the developing comprises an organic solvent.

12. The resist pattern-forming method according to claim 10, wherein a radioactive ray used in the exposing is an extreme ultraviolet ray or an electron beam.
